(19) United States
(12) Patent Application Publication
(10) Pub. No.: US 2026/0062798 A1
(43) Pub. Date: Mar. 5, 2026

(54) EVAPORATION MASK AND MANUFACTURING METHOD OF THE SAME

(71) Applicant: CANON KABUSHIKI KAISHA, Tokyo (JP)

(72) Inventor: TAKAYUKI SUMIDA, Kanagawa (JP)

(21) Appl. No.: 19/308,679

(22) Filed: Aug. 25, 2025

(30) Foreign Application Priority Data
Aug. 30, 2024 (JP) 2024-148394

(51) Int. Cl. C23C 16/04; C25D 5/02; C25D 7/00; H10K 71/16

(52) U.S. Cl. CPC C23C 16/042; C25D 5/022; C25D 7/00; H10K 71/166

(57) ABSTRACT

In a mask made of metal, a side wall of an opening has a boundary in a thickness direction and has a taper shape from the boundary toward the first surface and the second surface, and both a taper angle θ₁ on the first surface side on a deposition source side and another taper angle θ₂ on the second surface side on a deposition receiving substrate side are sharp angles and satisfy θ₁>θ₂.

### BACKGROUND

### Field of the Technology

The present disclosure relates to a high-definition metal evaporation mask and a manufacturing method of the same.

### Description of the Related Art

In recent years, the application range of an organic electroluminescence (EL) panel that uses an organic electroluminescence element (hereinafter, described as an “organic EL element”) as a light emitting element extends to big screen televisions as well as virtual reality (VR) headsets and dedicated goggles for use in VR, augmented reality (AR), and mixed reality (MR). While these applications demand very high pixel density (pixels per inch (ppi)) equal to or larger than 3000 ppi, for example, because an organic EL panel is generally manufactured by vacuum deposition processing of an organic material that is executed via an evaporation mask, a high-definition evaporation mask adapted to the above-described high pixel density is demanded.

As a technology relating to such a high-definition evaporation mask, a technology described in Japanese Patent Laid-Open No. 2002-305079 has been known. Japanese Patent Laid-Open No. 2002-305079 describes an evaporation mask that is used to form a thin-film pattern by a vacuum deposition method and includes an opening portion corresponding to the thin-film pattern. The evaporation mask includes not metal but monocrystalline silicon, and a mask opening is formed by anisotropic wet etching that utilizes crystal orientation dependence.

Because an evaporation mask made of monocrystalline silicon is manufactured using a photolithography technology and the anisotropic wet etching, openings can be formed with high processing accuracy. On the other hand, with increase in pixel density, a silicon thin part having openings becomes increasingly thin, which makes the brittle silicon material more susceptible to cracking or chipping at locations where flaws or scratches are present. In contrast to this, Japanese Patent Laid-Open No. 2002-305079 describes oppositely-oriented taper structures disposed on a deposition source side and a deposition receiving substrate side of the opening to reduce defect occurrence.

### SUMMARY

An aspect of the present disclosure is directed to providing a high-definition evaporation mask in which a defect of an opening is less likely to occur or generation of a foreign substance attributed to a deposited film is reduced or suppressed.

According to an aspect of the present disclosure, an evaporation mask made of metal, the evaporation mask includes a first surface on a deposition source side, a second surface on a side facing a deposition receiving substrate, and an opening penetrating from the first surface to the second surface, wherein a side wall surrounding the opening has a boundary between the first surface and the second surface and has a taper shape from the boundary toward the first surface and a taper shape from the boundary toward the second surface, and wherein, in a cross-section passing through the first surface, the second surface, and the opening, when a taper angle formed by the side wall and an extended line drawn from the first surface onto the opening is denoted by θ₁, and another taper angle formed by the side wall and an extended line drawn from the second surface onto the opening is denoted by θ₂, both the taper angles θ₁ and θ₂ are sharp angles and satisfy θ₁>θ₂.

According to another aspect of the present disclosure, a manufacturing method of an evaporation mask, the manufacturing method includes providing a seed layer on a surface of a substrate, forming, on the surface of the substrate, a first resist pattern having a taper angle θ₂ as an angle with respect to the surface, forming, on the first resist pattern, a second resist pattern having a taper angle θ₁ as an angle with respect to the surface, electrically precipitating a metal film in a space in the first and second resist patterns, forming an opening in the metal film by removing the first and second resist patterns, and removing the substrate and the seed layer from the metal film in which the opening is formed, wherein both the taper angles θ₁ and θ₂ are sharp angles and satisfy θ₁>θ₂.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram illustrating a schematic end view of a cross-section in a thickness direction of an evaporation mask according to an embodiment.

FIGS. 2A and 2B are diagrams each illustrating an enlarged view of an opening of the evaporation mask in FIG. 1.

FIG. 3 is a diagram illustrating a schematic plan view of an example of a high-definition metal evaporation mask.

FIGS. 4A to 4D are diagrams illustrating schematic end views in deposition processing using the high-definition metal evaporation mask.

FIG. 5 is a diagram illustrating an explanatory diagram of a deposition angle.

FIG. 6A is a diagram illustrating a schematic end view in a state of deposition using an evaporation mask according to an embodiment. FIG. 6B is a diagram illustrating a schematic end view in a state of deposition using a conventional evaporation mask.

FIG. 7 is an explanatory diagram illustrating a thickness of a taper portion of the evaporation mask according to an embodiment.

FIGS. 8A and 8B are explanatory diagrams illustrating a taper angle in another embodiment of an evaporation mask according to an embodiment.

FIGS. 9A to 9F are diagrams illustrating thickness-direction schematic end views of manufacturing processing of the evaporation mask according to an embodiment.

FIG. 10 is a diagram illustrating a thickness-direction cross-sectional schematic view of an example of an organic light emitting device.

FIG. 11 is a diagram illustrating a schematic view of an example of a display device.

FIG. 12A is a diagram illustrating a schematic view of an example of an imaging apparatus. FIG. 12B is a diagram illustrating a schematic view of an example of an electronic device.

FIG. 13A is a diagram illustrating a schematic view of an example of a display device. FIG. 13B is a diagram illustrating a schematic view of an example of a foldable display device.

FIG. 14 is a diagram illustrating a schematic view of an example of an illumination apparatus.

FIG. 15A and FIG. 15B are diagrams each illustrating a schematic view of an example of an automobile including a vehicle lighting device.

FIG. 16A is a diagram illustrating a schematic view of an example of a wearable device. FIG. 16B is a diagram illustrating a schematic view of an example of a wearable device having a configuration including an imaging apparatus.

FIG. 17A is a diagram illustrating a schematic view of an example of an image forming apparatus. FIGS. 17B and 17C are diagrams each illustrating a schematic view of a configuration in which a plurality of light emitting units of an exposure light source are disposed on an elongated substrate.

### DESCRIPTION OF THE EMBODIMENTS

Hereinafter, specific embodiments of an evaporation mask and evaporation processing using the evaporation mask according to the present disclosure will be described with reference to the accompanying drawings. In the following description and drawings, the same reference numerals are used to denote components that are common across a plurality of drawings. Therefore, common components may be described by cross-referencing multiple drawings, and redundant descriptions of components denoted by the same reference numerals may be omitted as appropriate.

An evaporation mask according to a present embodiment is made of metal, and includes a first surface, a second surface, and an opening penetrating from the first surface to the second surface, a side wall surrounding the opening has a boundary between the first surface and the second surface, and has a taper shape from the boundary toward the first surface and the second surface. Then, both a taper angle on the first surface side and a taper angle on the second surface are sharp angles and are different from each other.

A high-definition metal evaporation mask and deposition processing using the mask will be described.

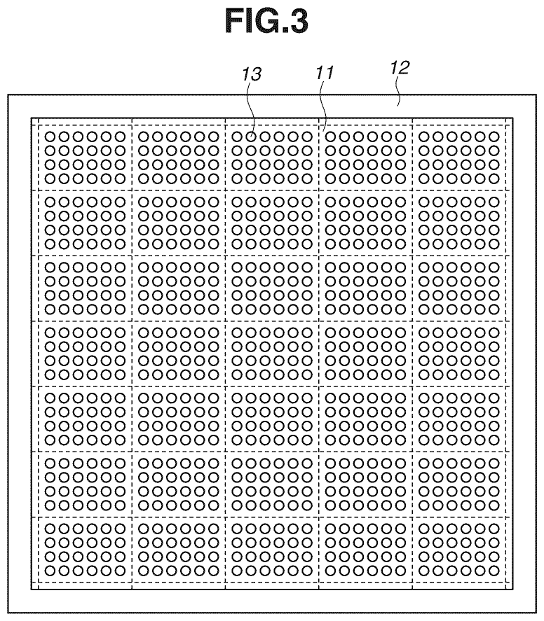

FIG. 3 is a diagram illustrating a schematic plan view of an example of a high-definition metal evaporation mask. As illustrated in FIG. 3, a plurality of openings 13 are arrayed in a mask 11. A mask frame 12 is bonded to the outer periphery of one surface of the mask 11. The position, an opening diameter, an opening pitch, and an opening shape of the openings 13 are determined by making appropriate selection in accordance with the position, a pixel size, a pixel pitch, and a pixel shape of pixels of a deposited substrate. Because a plurality of organic electroluminescence (EL) panels are generally manufactured from a deposited substrate, the openings 13 are disposed for each chip according to the corresponding panel size. In FIG. 3, cutting is performed along broken lines, whereby chips are separated. In FIG. 3, the shape of the openings 13 is illustrated as a circular shape but may be a rectangle or a polygonal shape according to a corresponding pixel shape. In addition, the array of the openings 13 may be a delta array or a staggered array which is appropriately selected according to a pixel array on the deposition receiving substrate. When no opening 13 is provided in a region between chips, the region may be thickened more than that of a region around the openings 13 so that the region is used as a so-called sash portion to increase the mechanical strength of the high-definition metal evaporation mask.

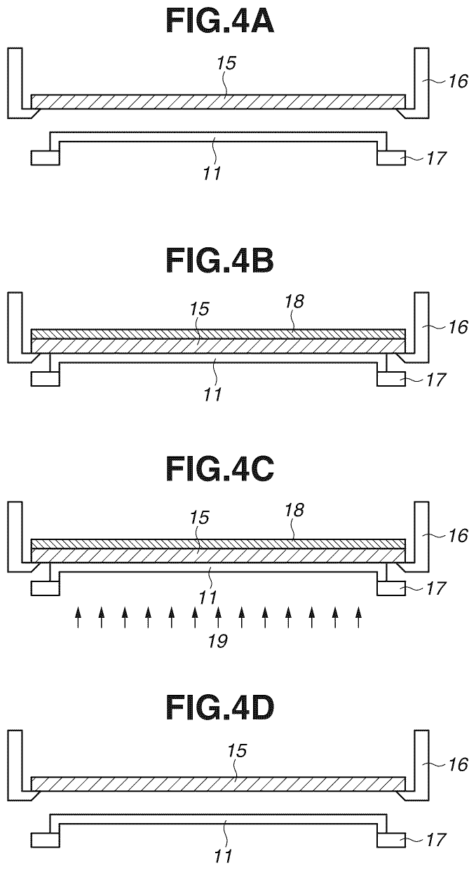

FIGS. 4A to 4D are diagrams schematically illustrating deposition processing using the high-definition metal evaporation mask. FIGS. 4A to 4D are thickness-direction cross-sectional schematic views of the deposition receiving substrate. The deposition processing includes processing of causing the mask 11 including a plurality of openings and a substrate (deposition receiving substrate) 15 including pixels to face each other in a deposition chamber, processing of aligning the substrate 15 and the mask 11, and processing of depositing a deposition material onto the substrate 15 through openings (not illustrated) of the mask 11.

As illustrated in FIG. 4A, the substrate 15 held by a substrate holding arm 16, and the mask 11 held by a mask stage 17 are positioned to face each other.

Then, for example, by moving either the substrate 15 or the mask 11 or both the substrate 15 and the mask 11, the substrate 15 and the mask 11 are aligned by referencing an alignment mark (not illustrated) disposed on the substrate 15 and an alignment mark (not illustrated) disposed on the mask 11.

After the alignment, the mask 11 is attracted by using a magnet 18 included in an upper portion of the substrate 15, and as illustrated in FIG. 4B, the substrate 15 and the mask 11 are brought into contact each other.

After that, as illustrated in FIG. 4C, a deposition material 19 is deposited on the substrate 15 via the plurality of openings of the mask 11.

After the deposition, the magnet 18 is separated from the substrate 15 to weaken its magnetic force, the attraction for the mask 11 is released, and as illustrated in FIG. 4D, the substrate 15 and the mask 11 are separated.

The evaporation mask according to the present embodiment is desirably used in the above-described deposition processing. Hereinafter, embodiments will be described with reference to the drawings. The dimensions, the materials, the shape, and the relative arrangement of components to be described below are not intended to limit the scope of the present disclosure to these unless specific description is given.

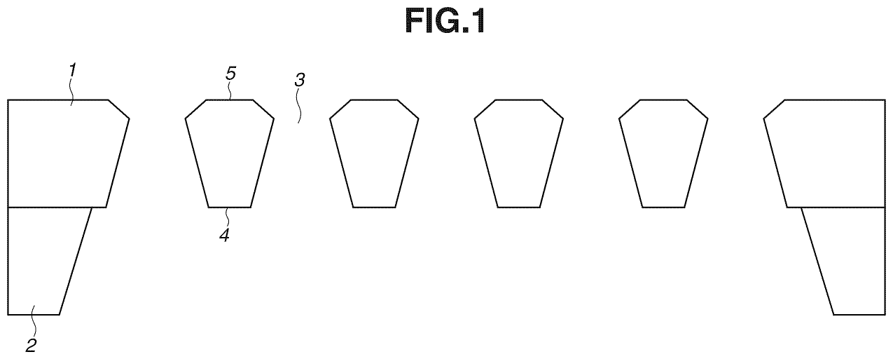

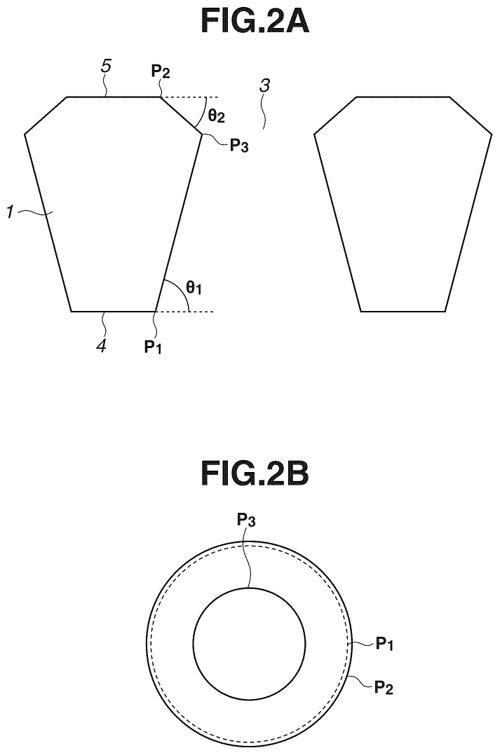

FIG. 1 is a diagram illustrating an end view of a thickness-direction cross-section including the first surface, the second surface, and an opening center according to an embodiment of an evaporation mask according to the present embodiment. In FIG. 1, one surface of an evaporation mask 1 is a first surface 4, and a surface on the opposite side of the first surface 4 is a second surface 5. An opening 3 is an opening penetrating from the first surface 4 to the second surface 5. A mask frame 2 is bonded to the outer periphery of the first surface 4 as necessary to suppress distortion and bending of the evaporation mask 1. FIG. 2A is a diagram illustrating an enlarged view of the vicinity of the opening 3, and FIG. 2B is a diagram illustrating a schematic plan view of the opening 3 viewed from the second surface 5 side.

In FIGS. 2A and 2B, a boundary P₁ is a boundary between a side wall of the opening 3 and the first surface 4, and a boundary P₂ is a boundary between the side wall and the second surface 5. In the present embodiment, as illustrated in FIG. 1, in a cross-section including the first surface 4, the second surface 5, and the center of the opening 3, the side wall surrounding the opening 3 has a boundary P₃ at a position separated by a predetermined distance from the first surface 4 and the second surface 5 in a thickness direction, and has a taper shape from the boundary P₃ toward the first surface 4 and the second surface 5. When a taper angle formed by the side wall and an extended line drawn from the first surface 4 toward the opening 3 at the boundary P₁ between the first surface 4 and the side wall is denoted by θ₁, and a taper angle formed by the side wall and an extended line drawn from the second surface 5 toward the opening 3 at the boundary P₂ between the second surface 5 and the side wall is denoted by θ₂, both the taper angles θ₁ and θ₂ are sharp angles and are different from each other. The directions of taper from the boundary P₃ toward the first surface 4 and the second surface 5 are opposite directions.

The mask 1 illustrated in FIGS. 1, 2A, and 2B is used in the deposition processing with the first surface 4 disposed on a deposition source side and the second surface 5 disposed on a deposition receiving substrate side, and in this processing, θ₁>θ₂ is satisfied.

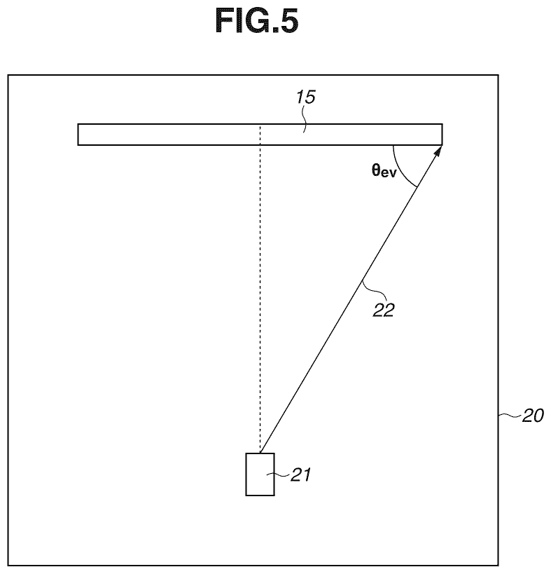

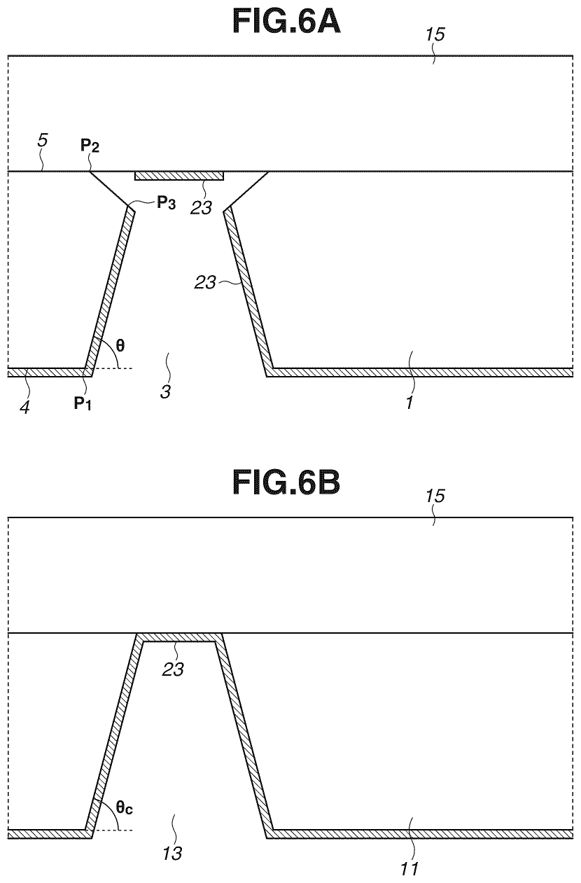

Here, a contact portion between the opening of the mask 1 and the deposition receiving substrate 15, and a taper angle and a deposition angle of the opening of the mask 1 will be described with reference to FIGS. 5, 6A and 6B.

FIG. 5 is a diagram illustrating a vertical-direction cross-sectional schematic view in a state of the deposition processing in a deposition chamber 20. FIGS. 6A and 6B are diagrams each illustrating a cross-sectional schematic view in a state in which the deposition receiving substrate 15 and the mask 1 are brought into contact each other by attracting the mask 1 by using the above-described magnet (not illustrated), FIG. 6A illustrates a state in which deposition has been performed using the mask 1 according to the present embodiment, and FIG. 6B illustrates a state in which deposition has been performed using a conventional mask 11.

As illustrated in FIG. 5, the deposition chamber 20 has a deposition source 21, such as a crucible, at the bottom.

A deposition apparatus includes a plurality of deposition chambers each corresponding to a different one of a plurality of its functional layers. Aside from the deposition chamber 20, the deposition apparatus may include a plurality of process chambers, such as a load lock chamber, a preparation chamber, a conveyance chamber, a relay chamber, a substrate stock chamber, and a sealing chamber into which and from which the deposition receiving substrate 15 are conveyed.

To achieve desired film thickness uniformity, a deposition angle of a deposition particle 22 incident from the deposition source 21 onto the deposition receiving substrate 15 is determined based on design factors, such as a distance (Target-Source; T-S distance) between the deposition receiving substrate 15 and the deposition source 21, a substrate offset position from the central axis of the deposition source 21, and a substrate size. The deposition angle varies also based on the position on the deposition receiving substrate 15 and varies based on relative positional relationship between the deposition source 21 and the deposition receiving substrate 15. For example, the deposition angle is approximately 90° at a certain region of the deposition receiving substrate 15 located immediately above the deposition source 21. However, the deposition angle becomes narrower, i.e., decreases, toward the edges of the deposition receiving substrate 15. When the T-S distance is set to 400 mm to 600 mm, on a silicon substrate on which the deposition receiving substrate 15 has a 12-inch size, a deposition angle (θₑᵥ) at the substrate edge is about 50° to 70°, depending also on an offset position. To maximize the number of elements on the deposition receiving substrate 15 for improved production efficiency, it is generally desirable that a taper angle θ, of the opening 13 of the mask 11 is matched to the smallest deposition angle (θₑᵥ) at the edge of the substrate end, to reduce shadowing of the deposition particle 22 caused by the opening 13 of the mask 11 that interferes with film formation on the deposition receiving substrate 15. To achieve this, the taper angles θ₁ and θ_{c} on the deposition source side of the opening 3 may be inclined in such a manner that the taper angles θ₁ and θ_{c} are set equal to or smaller than the deposition angle (θₑᵥ) as illustrated in FIG. 6A and FIG. 6B.

Further, reducing the taper angles θ₁ and θ_{c} can be achieved by reducing a film thickness of the mask 11.

This is because there is a mask structure issue that, when the taper angles θ₁ and θ_{c} are reduced, the neighboring openings 3 and 13 come into contact with each other on the first surface side. Especially in a high definition organic EL panel with a pixel density of over 3000 ppi, a pitch between pixels and a distance between centers of openings of masks corresponding to the pitch are about 8 μm or less. In this case, the thickness of a thin portion where the openings 3 and 13 exist is set to be 8.8 μm or less when the taper angle θ₁ or θ_{c} is 70°, and the thickness is set to be 3.8 μm or less when the taper angle θ₁ or θ_{c} is 50°, to achieve the above-described structure. These film thicknesses are very thin, and in a case where silicon is used as a mask material, a defect, such as a crack, easily occurs. Thus, when the thickness of a thin part of the mask is 8.8 μm or less, it is especially desirable that a metal mask film made of metal be formed.

In high pixel density deposition that is performed on a deposition receiving substrate using a high-definition evaporation mask, to reduce deposition blur to neighboring pixels, an evaporation mask and a deposited substrate sometimes brought into contact to each other. However, an evaporation mask having a thickness adapted to high pixel density is too thin, and a taper structure may be sometimes insufficient to prevent a defect generated in an opening at the time of the contact.

Further, an unintended foreign substance may be generated on a substrate through a repeated deposition processing, and by the foreign substance adhering to a mask during the process, the foreign substance can cause a decline in production yield ratio by causing a pixel defect as well as a stress concentration point on the mask at the time of contact which may cause a mask defect.

Here, an example of a high-definition mask for use in manufacturing of a light emitting device including high-definition pixels will be described. For example, at the pixel density equal to or larger than about 3000 ppi, a distance between pixels is set to be about 8 μm. In this case, a thin part of an evaporation mask made of silicon has a thickness of about 2 μm to 3 μm, which is very thin. Especially when high pixel density deposition is performed on a deposition receiving substrate by using a high-definition evaporation mask, to reduce deposition blur to neighboring pixels, it is desirable to bring the evaporation mask and the deposition receiving substrate into contact to each other. However, in a case of the mask thickness reduced to achieve the high pixel density, a tapered structure alone may be insufficient to prevent defects at the opening caused by contact.

Further, an unintended foreign substance may be generated on a substrate through a repeated deposition processing. The foreign substance may adhere to a mask during the process, and deposition may be affected in some cases. For example, in a case where deposition film is formed in a state in which a deposition receiving substrate is in contact with an evaporation mask, a continuous film deposited across the evaporation mask and the deposition receiving substrate is generated. After the film formation, when the evaporation mask is detached from the deposited substrate, the continuous film may be detached or fragmented by breakage and might become one of generation sources of foreign substances. Because these foreign substances are generated near pixels, the foreign substances may cause a decline in production yield ratio by causing a pixel defect as well as a stress concentration point on the mask at the time of contact which may cause a mask defect.

For example, as illustrated in FIG. 6B, in a case where the opening 13 has a straight structure not having, on the deposition receiving substrate 15 side, a taper oriented oppositely to a deposition source side, part of deposition particles incident at the taper angle θ_{c} are deposited on a contact line between the deposition receiving substrate 15 and the mask 11. A deposited film 23 is a continuous film extending over the deposition receiving substrate 15 and the mask 11. Thus, after the deposition, when attraction of the magnet for the mask 11 is released, and the deposition receiving substrate 15 and the mask 11 are separated, the continuous film breaks. The breakage causes film detachment and generates a foreign substance near pixels, which decreases a yield ratio.

In contrast to this, with a taper structure provided also on the deposition receiving substrate 15 side as illustrated in FIG. 6A, because a continuous film extending over the deposition receiving substrate 15 and the mask 1 is not formed, an occurrence of film detachment and the generation of a foreign substance that are attributed to a continuous film is able to be reduced. Furthermore, with the taper angle θ₁ on the deposition source side and the taper angle θ₂ on the deposition receiving substrate 15 side satisfying a relationship of θ₁>θ₂, shadowing of deposition particles from the deposition source is prevented by the taper structure on the deposition source side.

In the mask according to the present embodiment, a more desirable range of the taper angle θ₂ on the deposition receiving substrate 15 side is exemplified.

With the taper angle θ₁ on the deposition source side and the taper angle θ₂ on the deposition receiving substrate 15 side satisfying a relationship of θ₁>θ₂ as illustrated in FIG. 6A, shadowing of deposition particles and the breakage of a continuous film are able to be reduced, but it is desirable to reduce the taper angle θ₂ on the deposition receiving substrate 15 side. This is because, if the taper angle θ₂ can be set to be smaller, the taper angle θ₁ can be further reduced in accordance with the taper angle θ₂, which reduces shadowing and prevents continuous film formation also even in a case of a deposition receiving substrate, a mask, and a deposition source which are arranged in such a manner that deposition particles enter with a small deposition angle.

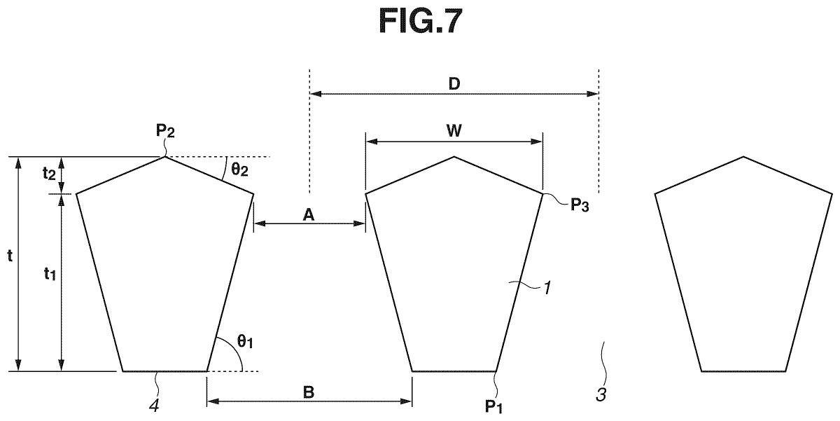

However, the taper angle θ₂ on the deposition receiving substrate 15 side has a specific angle at which n issue arises due to the structure of a high-definition metal evaporation mask. FIG. 7 is a diagram illustrating a schematic end view of a cross-section near the opening 3 in a case in which the taper angle θ₂ is set to be smaller. Here, when an opening on the deposition source side is regarded as a lower opening, a lower opening diameter is denoted by B. An opening on the deposited substrate side is regarded as an upper opening, and an upper opening diameter is denoted by A. The opening 3 is penetrated for the passage of deposition particles but can be characterized by tapered portions oriented in opposite directions on the deposition source side and the deposition receiving substrate side. That is, when a thickness of a taper portion on the deposition source side is described as a lower thickness t₁, a thickness of a taper portion on the deposition receiving substrate side is described as an upper thickness t₂. A sum of the thicknesses t₁ and t₂ is a mask film thickness t of the opening 3 of the mask 1. In other words, when a direction parallel to the second surface 5 is described as a first direction, and a direction vertical to the second surface 5 is described as a second direction, in the second direction, a length from the boundary P₃ to the first surface 4 is denoted by t₁, and a length from the boundary P₃ to the second surface 5 is denoted by t₂. A distance between the centers of the openings 3 in the first direction corresponds to a pixel pitch of the deposition receiving substrate, and is denoted by D. Furthermore, in a side wall partitioning the neighboring openings 3 and 3, a length of the side wall (side wall width) in the first direction at the boundary P₃ at which directions of tapers are reversed is denoted by W.

If just the taper angle θ₂ is reduced in a state in which the upper thickness t₂ of the mask 1 is fixed, a shape of an upper portion of the side wall increases sharpness. Ultimately, with the taper angle θ₂ at a specific angle or smaller, the height of the side wall on the outer circumferential side of the opening 3 provided at a position closest to the chip edge periphery among a plurality of openings 3 existing in the mask 1 (i.e., the inner circumferential side of the side wall of the sash portion) becomes lower. In a case of such a mask, when a deposition receiving substrate and the mask 1 are brought into contact by attraction of the magnet the shape of the opening 3 distorts due to insufficient height, and there arises an issue that a film with a desired film shape cannot be deposited on a deposition receiving substrate. To prevent this, the taper angle θ₂ is set to be larger than the specific angle at which a side wall upper part has a sharp shape. In other words, it is desirable that θ₂≥Arctan (2t₂/W) be satisfied.

In the mask according to the present embodiment, a desirable range of the upper thickness t₂ which is a thickness of a taper portion on the deposition receiving substrate side is exemplified.

As described above, by the taper portion on the deposition receiving substrate side, formation of a continuous film extending over the deposition receiving substrate and the mask is prevented, but the upper thickness t₂ has a desirable range. As illustrated in FIG. 6A, a deposited film is deposited on the deposition receiving substrate 15 above the boundary P₁ where taper directions are reversed. In a case where a desired film thickness of the deposited film is larger than the upper thickness t₂, the deposition reaches the boundary P₁ and a continuous film extending over the deposition receiving substrate 15 and the mask 1 is formed. Thus, it is desirable that the upper thickness t₂ is set to a desired film thickness of a targeted deposited film or larger. Because a film thickness of a light emission layer of an organic EL element is generally about 0.01 micrometer (μm), it is desirable that at least the upper thickness t₂ exceeds 10 nanometers (nm). Furthermore, in a case where a hole injecting layer and a hole transport layer are formed between the light emission layer and an anode, the upper thickness t₂ may be further increased by an amount corresponding to the thicknesses of these.

With the upper thickness t₂ set to be sufficiently large, the deposition of the deposited film does not reach the boundary P₁ during film formation. On the other hand, in a case where the upper thickness t₂ is set to be larger, as described above, there is a specific upper thickness t₂ at which an issue arises due to the structure of the mask 1. As illustrated in FIG. 7, when the taper angle θ₂ of the taper portion on the deposition receiving substrate side is fixed to a certain angle, with increase in the upper thickness t₂ with respect to the opening 3, an upper portion of the side wall becomes a sharp shape. Ultimately, if the upper thickness t₂ exceeds a specific upper thickness t₂, the height of the side wall on the outer circumferential side of the opening 3 provided at a position closest to the chip edge periphery among a plurality of openings 3 existing in the mask 1 (i.e., the inner circumferential side of the side wall of the sash portion) becomes lower. With such a mask 1, when a deposition receiving substrate and the mask 1 are brought into contact by attraction of the magnet, the shape of the opening 3 distorts due to insufficient height, and there arises an issue that a film with a desired film shape cannot be formed on a substrate.

To prevent this, the upper thickness t₂ may be set to be a thickness equal to or smaller than a specific upper thickness at which a side wall upper portion has a sharp shape. In other words, it is desirable that the taper angle θ₂ be set to satisfy t₂≤(W/2) tan θ₂.

In the present embodiment, a case where the side wall of the opening of the mask is not a straight line but a curved line or a bent line in a cross-sectional view will be described.

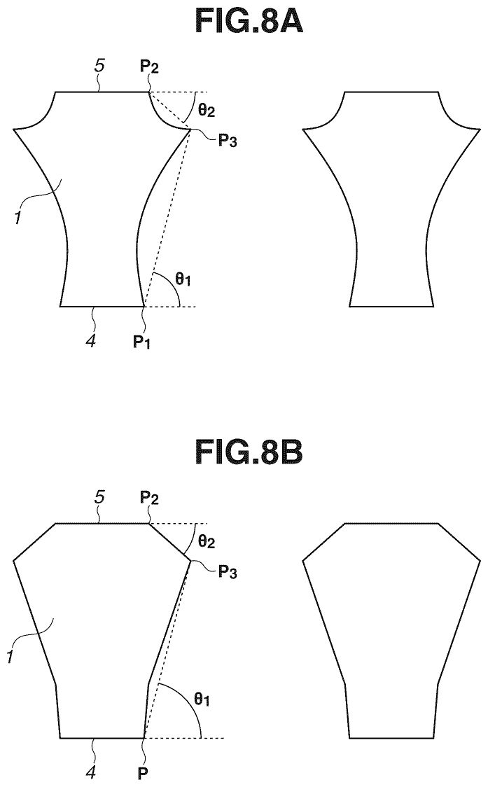

FIG. 8A is a diagram illustrating a case where the side wall of the opening 3 is a curved line in a thickness-direction cross-section of the mask, and FIG. 8B is a diagram illustrating a case where the side wall of the opening 3 is a bent line.

In the case illustrated in FIG. 8A, the taper angles θ₁ and θ₂ can be defined using the boundary P₁ on the deposition source side of the opening 3, the boundary P₃ at which taper directions are reversed, and the boundary P₂ on the deposition receiving substrate side. In other words, with an angle formed by a straight line connecting the boundaries P₁ and P₃, and an extended line of the first surface 4 of the mask 1 is denoted by θ₁, and an angle formed by a straight line connecting the boundaries P₂ and P₃, and an extended line of the second surface 5 of the mask 1 is denoted by θ₂, an effect of the present embodiment can be obtained.

Even in a case where a straight line portion includes a plurality of bend points, as illustrated in FIG. 8B, the taper angles θ₁ and θ₂ can be defined using the boundary P₁ on the deposition source side of the opening 3, the boundary P₃ at which taper directions are reversed, and the boundary P₂ on the deposition receiving substrate side. In other words, with an angle formed by a straight line connecting the boundaries P₁ and P₃, and an extended line of the first surface 4 of the mask 1 is denoted by θ₁, and an angle formed by a straight line connecting the boundaries P₂ and P₃, and an extended line of the second surface 5 of the mask 1 is denoted by θ₂, an effect of the present embodiment can be obtained.

A manufacturing method of a mask according to the present embodiment will be described. The mask according to the present embodiment is able to be manufactured by the following processing:
processing of providing a seed layer on a substrate,
processing of forming a first resist pattern having a taper with the taper angle θ₂, on the substrate,
processing of forming a second resist pattern having a taper with the taper angle θ₁, on the first resist pattern,
processing of electrically precipitating a metal film in a space in the first and second resist patterns,
processing of forming an opening in a metal film by removing the first and second resist patterns, and
processing of removing the substrate and the seed layer from the metal film in which the opening has been formed.

Hereinafter, embodiments will be specifically described.

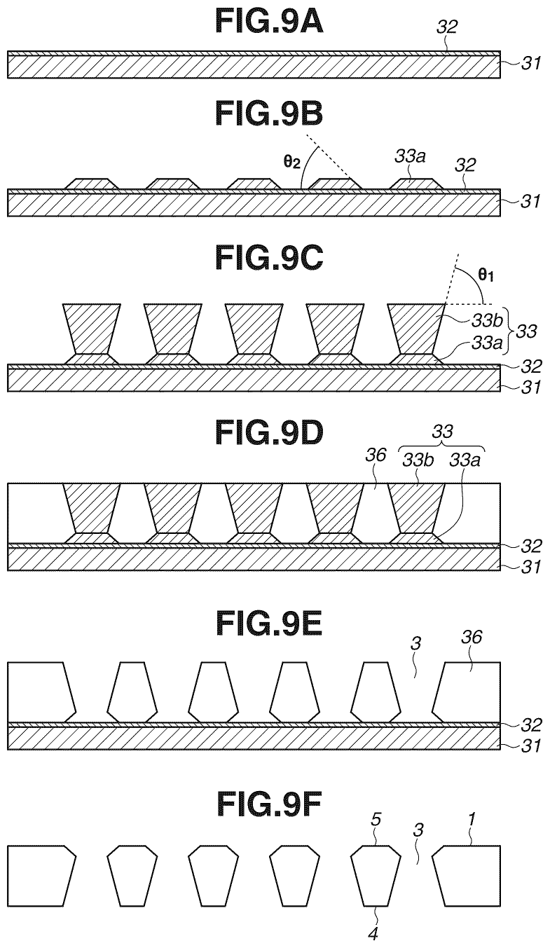

FIGS. 9A to 9F are diagrams illustrating manufacturing processing of the mask illustrated in FIG. 1. FIGS. 9A to 9F are thickness-direction cross-sectional schematic views of the mask.

As illustrated in FIG. 9A, a glass substrate 31 is prepared, and a chrome film 32 is formed on the glass substrate 31 by sputtering. Because the chrome film 32 is a seed layer for providing conductivity in subsequent plating processing, the material of the film is not limited to chrome as long as conductivity is able to be provided.

Then, as illustrated in FIG. 9B, a first resist pattern 33a having the taper angle θ₂ is formed. Specifically, first of all, a positive resist is applied by spin coating, and pre-bake is performed. Exposure and development are performed via a photomask, and after the development, the positive resist is cured by post-bake. In this processing, control is performed by using a grayscale mask as exposure/development conditions and the photomask, whereby the first resist pattern 33a having a predetermined taper angle θ₂ can be formed.

As illustrated in FIG. 9C, a second resist pattern 33b having the taper angle θ₁ is formed. Specifically, a negative resist is applied onto the first resist pattern 33a by spin coating, and pre-bake is performed. In a case where the thickness of the first resist pattern 33a is large, striation attributed to the resist pattern may occur depending on a rotation condition of spin coating, but in such a case, a negative resist may be applied not by spin coating but by spraying. Exposure and development are performed via a photomask, and after the development, the negative resist is cured by post-bake. In this processing, control is performed by using exposure/development conditions, whereby the second resist pattern 33b having a predetermined taper angle θ₁ can be formed. Thus, a resist pattern 33 including the first resist pattern 33a and the second resist pattern 33b connected in a film thickness direction is obtained.

Next, as illustrated in FIG. 9D, electric plating is performed on an air gap of the resist patterns 33 using a chrome film 32 of a base as an electrode, and the space is filled with a precipitated metal film 36. As metal to be plated, iron-nickel alloy or a nickel-cobalt alloy is desirable because a thermal expansion coefficient can be set to be low. For plating bath, a general plating composition consisting mainly of nickel sulfate, cobalt sulfate, and iron sulfate may be used. It is desirable that the thickness of the metal film 36 should not exceed the thickness of the resist pattern 33. If the thickness of the metal film 36 exceeds the thickness of the resist pattern 33, the top surface of the resist pattern 33 is covered with the metal film 36, which leads to difficulty in detaching the resist later. According to electroforming that uses such a resist and plating, it is possible to avoid dimensional limitation of an opening diameter and a thickness that is attributed to a particular taper angle determined based on crystal orientation in a case where anisotropic wet etching of monocrystalline silicon is used.

Next, as illustrated in FIG. 9E, the resist pattern 33 is removed using resist removing liquid, and a metal film 36 with the openings 3 which have been occupied by the resist patterns 33 is obtained. If a residue of the resist removing liquid remains, the resist residue may be removed by plasma processing that uses oxygen or argon.

Lastly, as illustrated in FIG. 9F, the mask 1 is obtained by detaching the metal film 36 from the chrome film 32 and the glass substrate 31. Furthermore, a mask frame (not illustrated) is bonded to the outer periphery of the mask 1 as a configuration settable to a deposition apparatus as necessary. When the mask frame is bonded, fixing such as welding or screwing may be appropriately performed in a state in which general tension is added.

In this manner, the mask 1 made of metal that includes the openings 3 having oppositely-oriented tapers on both the surface on the deposition source side and the surface on the deposition receiving substrate side, which serve as the first surface 4 and the second surface 5, respectively, is obtained. The mask 1 is a high-definition metal evaporation mask adapted to high pixel density equal to or larger than 3000 ppi, for example, in which a film thickness of a part where the openings 3 exist is thin, and an interval between the openings 3 is very narrow.

A manufacturing method of an organic light emitting device that uses the mask according to the present embodiment will be described.

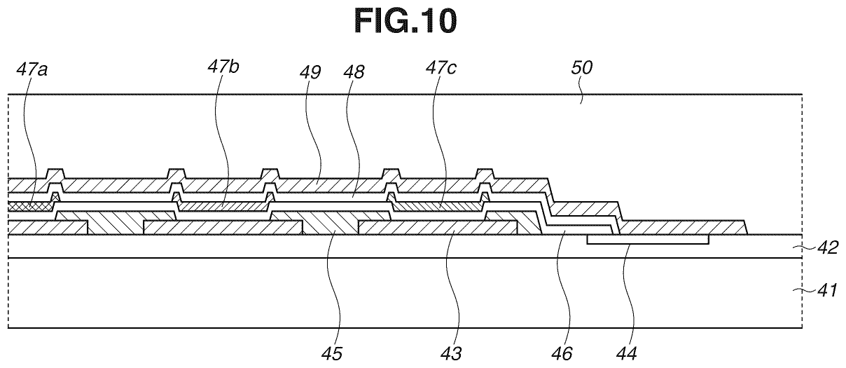

The organic light emitting device is manufactured by a plurality of processes. First of all, a substrate on which a drive circuit including a transistor and a capacitance for controlling light emission for each of the pixels corresponding to red, green, and blue is formed is prepared. Next, a hole injecting layer and a hole transport layer are formed on each pixel as necessary. Next, a light emission layer is formed using a vacuum deposition method for each color of red, green, and blue. Next, an electron transport layer, an electron injecting layer, and a cathode are formed. Here, the hole injecting layer and the hole transport layer or the electron transport layer and the electron injecting layer may be formed in common in such a manner that the thicknesses become the same in all colors in view of productivity. Alternatively, to obtain an optical interference effect, the hole transport layer and the electron transport layer may be formed by varying the thickness among colors. Each component will be described with reference to FIG. 10.

FIG. 10 is a diagram illustrating a thickness-direction cross-sectional schematic view of a substrate of an example of an organic light emitting device including light emission layers with a plurality of colors.

In the device illustrated in FIG. 10, an insulation layer 42, a first electrode 43 that is to serve as a pixel electrode, a contact region 44 for applying current to a second electrode 49, a pixel isolation layer 45, a first organic layer 46, a first light emission layer 47a, a second light emission layer 47b, a third light emission layer 47c, a second organic layer 48, the second electrode 49 are formed and provided on a substrate 41. Normally, the first, second, and third light emission layers 47a, 47b, and 47c has light emission functions of red, green, and blue, respectively. A protective layer 50 and furthermore, a color filter (not illustrated) and a microlens may be provided on the second electrode 49. In a case where the light emission layers 47a to 47c that emit light in the colors are differently colored using a high-definition metal evaporation mask for pixels corresponding to red, green, and blue, a color filter may be omitted, but in a case where a color filter is provided with a view to improving color purity, a planarization layer may be provided between the color filter and the protective layer. The planarization layer may be formed of acrylic resin. The same applies to a case where a planarization layer is provided between the color filter and the microlens.

Each member will be described.

### [Substrate]

The materials of the substrate 41 include quartz, glass, silicon wafers, resin, and metal. A switching element, such as a transistor, and a wire are disposed on the substrate 41, and the insulation layer 42 may be disposed thereon. As the insulation layer 42, the material is not limited as long as a contact hole can be formed in such a manner that a wire can be formed between the insulation layer 42 and the first electrode 43, and insulation from an unconnected wire can be ensured. For example, resin, such as polyimide, silicon oxide, or silicon nitride may be used. Especially for applications targeting high pixel density, a silicon substrate is desirable.

### [Electrode]

One of the first electrode 43 and the second electrode 49 may be an anode, and the other one may be a cathode. In a case where an electric field is applied in a direction in which an organic light emitting element emits light, an electrode with high potential is an anode, and the other one is a cathode. It can also be said that an electrode that supplies a hole to a light emission layer is an anode, and an electrode that supplies an electron is a cathode.

As for the material used for the anode, one with a relatively high work function is desirable. For example, single metal, such as gold, platinum, silver, copper, nickel, palladium, cobalt, selenium, vanadium, and tungsten, a composite containing these, or an alloy obtained by combining these, or metal oxide, such as tin oxide, zinc oxide, indium oxide, indium tin oxide (ITO), or zinc indium oxide may be used. A conductive polymer, such as polyaniline, polypyrrole, and polythiophene can also be used.

Among these electrode materials, a single type may be used alone, or two or more types may be used together. In addition, an anode may have a single-layer structure, or may have a multilayered structure.

In a case where an electrode is used as a reflective electrode, for example, chromium, aluminum, silver, titanium, tungsten, molybdenum, or an alloy or these layered in a layer may be used. By using the above-described material, an electrode may function as a reflective film not having a function as an electrode. In a case where an electrode is used as a transparent electrode, an oxide transparent conductive layer, such as indium tin oxide (ITO) or indium zinc oxide, may be used, but the material of the electrode is not limited to these.

A photolithography technology may be used for the formation of electrodes.

On the other hand, as for the material used for the cathode, one with a relatively small work function is desirable. Examples include single metal, such as alkali metal such as lithium, alkaline earth metal, such as calcium, aluminum, titanium, manganese, silver, lead, or chromium, or a composite containing these. Alternatively, an alloy obtained by combining these single metals may also be used. For example, magnesium-silver, aluminum-lithium, aluminum-magnesium, silver-copper, or zinc-silver may be used. Metal oxide, such as indium tin oxide (ITO) may also be used. Among these electrode materials, a single type may be used alone, or two or more types may be used together. In addition, a cathode may have a single-layer structure, or may have a multilayered structure. Among the above-described materials, it is desirable to use silver, and to reduce the agglomeration of silver, it is further desirable to use a silver alloy. As long as the agglomeration of silver can be reduced, a ratio of alloy is not limited. For example, a ratio between silver and another type of metal may be 1:1 or 3:1.

The cathode may function as a top emission element by using an oxide conductive layer, such as ITO or silver having a film thickness with semi-permeability, or may function as a bottom emission element by using a reflective electrode, such as aluminum (Al), and the function of the cathode is not specifically limited. The formation method of the cathode is not specifically limited, but it is more desirable to use direct-current and alternating-current sputtering methods because of good coverage of a film and potential to lower resistance.

### [Pixel Isolation Layer]

The pixel isolation layer 45 is formed by a silicon nitride (SiN) film, a silicon oxynitride (SiON) film, or a silicon oxide (SiO) film formed by using a chemical vapor deposition (CVD) method. To increase resistance in an in-plane direction of an organic compound layer, it is desirable that an organic compound layer such as a hole transport layer in particular is formed to have a thin film thickness on the side wall of the pixel isolation layer 45. Specifically, a taper angle of the side wall of the pixel isolation layer 45 and a film thickness of the pixel isolation layer 45 are increased to increase shadowing at the time of deposition, whereby the side wall having a thin film thickness is formed.

On the other hand, it is desirable that a side wall taper angle of the pixel isolation layer 45 and a film thickness of the pixel isolation layer 45 are adjusted to such extent that a space is not created in the protective layer 50 formed on the pixel isolation layer 45. Because a space is not created in the protective layer 50, generation of a defect in the protective layer 50 can be reduced. Since generation of a defect in the protective layer 50 is reduced, it is possible to reduce reliability decline, such as generation of a dark spot and an occurrence of a conductivity failure of the second electrode 49.

Even when the taper angle of the side wall of the pixel isolation layer 45 is not steep, as long as the taper angle falls within the range from 60° to 90°, it is possible to effectively suppress charge leakage to neighboring pixels. A film thickness of the pixel isolation layer 45 is desirably 10 nm to 150 nm. The structure including the first electrode 43 and not including the pixel isolation layer 45 can obtain a similar effect. However, in this case, a film thickness of the first electrode 43 is set to a half or less of that of the organic compound layer (46, 47a, 47b, 47c, 48), or the end of the first electrode 43 is made into a forward taper smaller than 60°, which is desirable because short-circuiting of an organic light emitting element can be reduced.

### [Organic Compound Layer]

A layered member including the first organic layer 46, the light emission layers 47a to 47c, and the second organic layer 48 that is held between the first electrode 43 and the second electrode 49 is called an organic compound layer. The first organic layer 46 and the second organic layer 48 include any one or two or more of a hole injecting layer, a hole transport layer, an electron blocking layer, a hole element layer, an electron transport layer, or an electron injecting layer depending on its function. Each layer of the organic compound layer mainly includes an organic compound but may contain an inorganic atom or an inorganic compound. For example, the organic compound layer may contain copper, lithium, magnesium, aluminum, iridium, platinum, molybdenum, or zinc.

In a case where a plurality of light emission layers is layered, a charge generation layer may be disposed between upper and lower light emission layers. The charge generation layer may include an organic compound with a lowest unoccupied molecular orbital (LUMO) of −5.0 eV or less. The charge generation layer may include a compound with the LUMO lower than that of a hole transport layer, and the LUMO of the charge generation layer may be lower than a highest occupied molecular orbital (HOMO) of the hole transport layer. Here, orbital energy of an organic compound layer may be orbital energy of an organic compound in which a mass ratio of the organic compound layer is largest.

Here, HOMO and LUMO are described as high when they are closer to the vacuum level. A state in which LUMO of the charge generation layer is lower than HOMO of the hole transport layer indicates a state in which LUMO of the charge generation layer is closer to the vacuum level than to HOMO of the hole transport layer.

In this specification, HOMO and LUMO may be calculated using molecular orbital calculation. The molecular orbital calculation may be performed based on a density functional theory (DFT), and may be performed using B3LYP as a functional and 6-31G* as a base function. The molecular orbital calculation may be performed using, for example, Gaussian09 (Gaussian09, RevisionC.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.).

In this specification, HOMO and LUMO may be calculated using ionization potential and band gap. The HOMO may be estimated by measuring ionization potential. The ionization potential may be measured by dissolving a measurement target compound into solvent such as toluene and using a measuring apparatus, such as AC-3. The band gap may be measured by measurement of dissolving a measurement target compound into solvent, such as toluene and emitting excitation light. By measuring an absorption end of the excitation light, the band gap can be measured. Alternatively, by depositing a measurement target compound on a substrate, such as a glass substrate, and emitting excitation light to a deposited film, whereby the band gap is measured. The measurement can measure the band gap by measuring an absorption end of an absorption spectrum at which the deposited film absorbs the excitation light.

LUMO can be calculated using values of the band gap and the ionization potential. By subtracting a value of the ionization potential from a value of the band gap, it is possible to estimate LUMO.

LUMO may also be estimated from a reduction potential. For example, one-electron reduction potential is estimated using cyclic voltammetry (CV) measurement. The CV measurement can be performed, for example, in dimethylformamide (DMF) solution of 0.1 M tetrabutylammonium perchlorate, using an Ag/Ag⁺ reference electrode, a Pt counter electrode, and a glassy carbon working electrode. LUMO can be estimated by adding a difference between the reduction potential of the obtained compound and the reduction potential of ferrocene to −4.8 eV.

Examples of a method to be used for forming of the organic compound layer is a dry process, such as a vacuum deposition method, an ionized deposition method, sputtering, or a plasma method. Instead of the dry process, a wet process of forming a layer using a known application method (e.g., spin coating, dipping, a casting method, a Langmuir-Blodgett (LB) method, an inkjet method, etc.) by dissolution in an appropriate solvent may also be used.

When a layer is formed using the vacuum deposition method or a solution application method, crystallization is less likely occur, and good temporal stability can be obtained. In the case of forming a film using an application method, the film may be formed in combination with an appropriate binder resin.

Examples of the above-described binder resin include polyvinyl carbazole resin, polycarbonate resin, polyester resin, acrylonitrile butadiene styrene (ABS), acrylic resin, polyimide resin, phenol resin, epoxy resin, silicon resin, and urea resin, but the binder resin is not limited to these.

Among these binder resins, a single type may be used along as a homopolymer or a copolymer, or two or more types may be mixed and used. Furthermore, as necessary, a known additive agent, such as a plasticizer, an antioxidant, or an ultraviolet absorber may be used in combination.

The evaporation mask according to the present embodiment is desirably used in the deposition processing of the light emission layers 47a to 47c in the organic compound layer. In a case where a deposition material is a light emission layer, for example, light emission materials respectively correspond to red, green, and blue, and in a case where red is selected as a first color, films may be sequentially formed using green as a second color and blue as a third color, for example. A light emission material of each color may be a single material, or may be a multi-component-based material including a so-called host and a light emission dopant. There are two methods for deposition of the second and third colors.

The first method is a method of preparing masks with opening positions varying for each color. In this case, the same process as that of the first color may be repeated by changing masks for the second and subsequent colors. The other method is a method of preparing a mask for one color, and differently coloring pixels by shifting the position of the mask for the second and third colors. Changing the mask is unnecessary, and the number of masks can be reduced in a case where the pixel sizes and pitches of the colors are the same, and pixels are repetitively arranged, but mask cleaning frequency increases because a deposited film is deposited on the rear surface of the mask for each color. Thus, these two methods may be appropriately selected in view of productivity.

Main light emission materials relating to light emission functions include a fused ring compound (e.g., fluorene derivative, naphthalene derivative, pyrene derivative, perylene derivative, tetracene derivative, anthracene derivative, rubrene, etc.), quinacridone derivative, coumarin derivative, stilbene derivative, an organoaluminium complex, such as tris(8-quinolinolate)aluminum, an iridium complex, a platinum complex, a rhenium complex, a copper complex, an europium complex, a ruthenium complex, and a polymer derivative, such as a poly(phenylene vinylene) derivative, a poly(fluorene) derivative, and a poly(phenylene) derivative.

### [Protective Layer]

The protective layer 50 may be disposed on the second electrode 49. For example, by bonding glass applied with a moisture absorption agent, onto the second electrode 49, the inrush of water or the like into an organic compound layer can be reduced, and the occurrence of a display failure can be reduced. The inrush of water or the like into an organic compound layer may be reduced by providing a passivation film, such as a silicon nitride film on the cathode. For example, the protective layer 50 may be formed by forming the cathode and then conveying the cathode to another chamber while keeping a vacuum state, and forming a silicon nitride film with a thickness of 2 μm by a chemical vacuum deposition (CVD) method. After a film is formed using the CVD method, the protective layer 50 may be provided using an atomic layer deposition method (ALD method). The material of a film to be formed using the ALD method is not limited, but may be silicon nitride, silicon oxide, or aluminum oxide. On the film formed using the ALD method, silicon nitride may be further formed using the CVD method. The film thickness of the film formed using the ALD method may be smaller than that of the film formed using the CVD method. Specifically, the film thickness may be equal to or smaller than 50%, and furthermore, may be equal to or smaller than 10%.

### [Color Filter]

A color filter (not illustrated) may be disposed on the protective layer 50. For example, a color filter factoring in the size of an organic light emitting element may be disposed on a different substrate, and the different substrate and a substrate on which the organic light emitting element is disposed may be bonded, or the patterning of color filters may be performed on the above-described protective layer using the photolithography technology. The color filters may be made of high-polymer material.

### [Planarization Layer]

A planarization layer (not illustrated) may be disposed between the color filter (not illustrated) and the protective layer 50.

The planarization layer is disposed for the purpose of reducing unevenness of a lower layer. The planarization layer may be called a material resin layer without limiting its purpose. The planarization layer may be made of an organic compound and may be made of whichever of low molecular material and high molecular material, but is desirably made of high-polymer material.

Planarization layers may be disposed above and below the color filter, and materials included in the planarization layers may be the same or different. Specifically, examples of the materials include polyvinyl carbazole resin, polycarbonate resin, polyester resin, ABS resin, acrylic resin, polyimide resin, phenol resin, epoxy resin, silicon resin, and urea resin.

### [Microlens]

The organic light emitting device may include an optical member, such as a microlens, on its light emission side. The microlens may be made of acrylic resin or epoxy resin. The microlens may be disposed for the purpose of increasing an amount of light to be extracted from the organic light emitting device and controlling the direction of light to be extracted. The microlens may have a hemispherical shape. In a case where the microlens has a hemispherical shape, among tangent lines having contact with the hemisphere, there is a tangent line parallel to the insulation layer, and a contact point between the tangent line and the hemisphere corresponds to a vertex of the microlens. The vertex of the microlens can be similarly determined also in an arbitrary cross-sectional view. That is, among tangent lines having contact with a semicircle of the microlens in the cross-sectional view, there is a tangent line parallel to the insulation layer, and a contact point between the tangent line and the semicircle corresponds to the vertex of the microlens.

A midpoint of the microlens can also be defined. In the cross section of the microlens, an imaginary line segment from a point at which the shape of an arc ends, to a point at which the shape of another arc ends is set, and a midpoint of the imaginary line segment can be called as a midpoint of the microlens. The cross section in which the vertex and the midpoint are determined may be a cross section vertical to the insulation layer.

The microlens has a first surface including a convex part, and a second surface opposite to the first surface. It is desirable that the second surface is disposed at a position closer to a functional layer side than the first surface. To employ such a configuration, the microlens is formed on a light emitting device. In a case where a functional layer is an organic layer, it is desirable to avoid high-temperature processing in manufacturing processing. In a case of employing a configuration in which the second surface is disposed at a position closer to a functional layer side than the first surface, glass-transition temperatures of all organic compounds included in the organic layer are desirably 100° C. or more, and more desirably 130° C. or more.

### [Counter Substrate]

A counter substrate may be disposed on the planarization layer. Because the counter substrate is disposed at a position facing the above-described substrate, the counter substrate is called as a counter substrate. The material of the counter substrate may be the same as that of the above-described substrate. In a case where the above-described substrate 41 is regarded as a first substrate, the counter substrate may be regarded as a second substrate.

### [Pixel Circuit]

The organic light emitting device may include a pixel circuit connected to an organic EL element. The pixel circuit may be an active-matrix circuit that independently controls the light emission of a first light emitting element and a second light emitting element. The active-matrix circuit may be a voltage-programmed pixel circuit or a current-programmed pixel circuit. A drive circuit includes a pixel circuit for each pixel. The pixel circuit may include a light emitting element, a transistor that controls light emission brightness of the light emitting element, a transistor that controls a light emission timing, a capacitance holding a gate voltage of the transistor that controls light emission brightness, and a transistor for connecting to the ground (GND) not via the light emitting element.

The light emitting device includes a display region, and a peripheral region disposed around the display region. The display region includes a pixel circuit, and the peripheral region includes a display control circuit. The mobility of a transistor included in the pixel circuit may be smaller than the mobility of a transistor included in the display control circuit.

The gradient of the current-voltage characteristic of the transistor included in the pixel circuit may be smaller than the gradient of the current-voltage characteristic of the transistor included in the display control circuit. The gradient of the current-voltage characteristic can be measured based on so-called Vg-Ig characteristics.

The transistor included in the pixel circuit is a transistor connected to a light emitting element, such as the first light emitting element.

### [Pixel]

The organic light emitting device includes a plurality of pixels. Pixels include subpixels that emit light with colors different from each other. Subpixels may have RGB light emission colors, for example.

In the pixel, a region also called a pixel opening emits light. This region is the same as a first region.

The pixel opening may be smaller than or equal to 15 μm, and may be larger than or equal to 5 μm. More specifically, the pixel opening may be 11 μm, 9.5 μm, 7.4 μm, 6.4 μm, or the like.

An interval between subpixels may be smaller than or equal to 10 μm. Specifically, an interval between subpixels may be 8 μm, 7.4 μm, or 6.4 μm.

Pixels can employ a known arrangement configuration in a plan view. For example, the arrangement may be striped arrangement, delta arrangement, Pentile arrangement, or Bayer arrangement. The shape of the subpixels in a plan view may be any of known shapes. For example, the shape is a quadrangle, such as a rectangle or a rhomboid, or a hexagon. A shape that is not an exact rectangle and resembles a rectangle is also included in rectangles. The shape of subpixels and a pixel array may be used in combination.

An example of the organic light emitting device will be described. A silicon substrate is used as the substrate 41. A layered structure of Ti/TiN/AlCu (65-nm thickness) is layered as the anode, i.e., the first electrode 43, a hole injecting layer (8-nm thickness) and a hole transport layer (37-nm thickness) are layered as the first organic layer 46, the light emission layers 47a to 47c (10-nm thickness) are sequentially formed by the vacuum deposition method using the evaporation mask according to the present embodiment, and then, a hole blocking layer (34 nm), an electron transport layer (20 nm), and an electron injecting layer (0.5 nm) are layered as the second organic layer 48. Lastly, a layered structure of magnesium and silver (total thickness of 15 nm) is layered as the cathode (i.e., second electrode 49). Furthermore, the protective layer 50 may be served as a protective layer for moisture transmission prevention by forming the cathode and then conveying the cathode to another chamber while keeping a vacuum state, and forming a silicon nitride film with a thickness of 2 μm by the CVD method. In the present embodiment, only the light emission layers 47a to 47c are formed for each corresponding pixels using the mask according to the present embodiment, and as other functional layers, general evaporation masks that can be used in common on all the first electrodes 43 as common layers may be used.

### [Use Application of Organic Light Emitting Device]

An organic light emitting device manufactured using an evaporation mask according to the present embodiment may be used as a component of a display device or an illumination apparatus. Aside from these, the use applications include an exposure light source of an electrophotographic image forming apparatus, a backlight of a liquid crystal display device, and a light emitting device including a color filter in a white light source.

The display device may be an image information processing apparatus that includes an image input unit for inputting image information from an area charge-coupled device (CCD), a linear CCD, or a memory card, and an information processing unit for processing the input information, and displays an input image on a display unit.

A display unit included in an imaging apparatus or an inkjet printer may have a touch panel function. A driving method of the touch panel function is not specifically limited, and the touch panel may be an infrared touch panel, a capacitive touch panel, a resistive touch panel, or an electromagnetic touch panel. The display apparatus may be used in a display unit of a multifunctional printer.

Next, a display device that uses an organic light emitting device will be described with reference to the drawings.

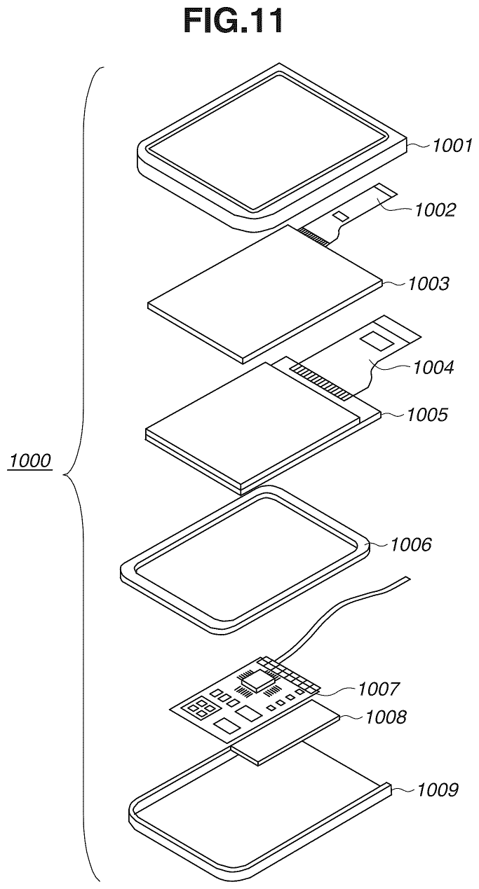

FIG. 11 is a diagram illustrating a schematic view of an example of a display device. A display device 1000 includes a touch panel 1003, a display panel 1005, a frame 1006, a circuit substrate 1007, and a battery 1008 between an upper cover 1001 and a lower cover 1009. Flexible printed circuits (FPCs) 1002 and 1004 are respectively connected to the touch panel 1003 and the display panel 1005. A transistor is printed on the circuit substrate 1007. The battery 1008 may be omitted in a case where the display device 1000 is not a portable device. Even in a case where the display device 1000 is a portable device, the battery 1008 may be disposed at a different position.

The display device 1000 according to the present embodiment may include a color filter having a red color, a green color, and a blue color. In the color filter, the red color, the green color, and the blue color may be arranged in the delta array.

The display device 1000 according to the present embodiment is used in a display unit of a mobile terminal. In this case, the display device 1000 may have both a display function and an operation function. Examples of the mobile terminal include a mobile phone, such as a smartphone, a tablet, and a head-mounted display.

The display device 1000 according to the present embodiment is used in a display unit of an imaging apparatus including an optical unit including a plurality of lenses, and an image sensor for receiving light having passed through the optical unit. The imaging apparatus may include a display unit that displays information acquired by the image sensor. The display unit may be a display unit exposed to the outside of the imaging apparatus or a display unit arranged within a viewfinder. The imaging apparatus may be a digital camera or a digital video camera.

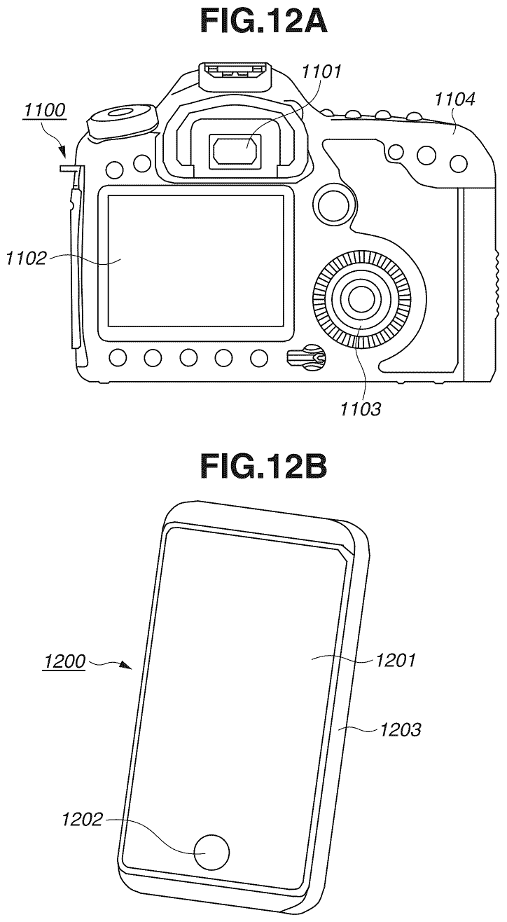

FIG. 12A is a diagram illustrating a schematic view of an example of an imaging apparatus. An imaging apparatus 1100 includes a viewfinder 1101, a back-surface display 1102, an operation unit 1103, and a housing 1104. The viewfinder 1101 includes a display device. In this case, the display device may display a captured image as well as environmental information and an image capturing instruction. The environmental information may include intensity of external light, orientation of external light, a speed at which a subject moves, and a possibility of a subject being shielded by a shielding object.

Because a timing appropriate to image capturing is a small amount of time, it is desirable to display information as quickly as possible. Thus, it is desirable to use a display device using an organic light emitting device. This is because the organic light emitting device has high response speed. The display devices using the organic light emitting device may be used more desirably in apparatuses requiring display speed, and may be used more desirably than a liquid crystal display device.

The imaging apparatus 1100 may further include an optical unit (not illustrated). The optical unit includes a plurality of lenses that form an image onto an image sensor accommodated in the housing 1104. By adjusting relative positions of the plurality of lenses, a focal point is able to be controlled. This operation can also be performed automatically. The imaging apparatus may be called a photoelectric conversion apparatus. As an image capturing method, the photoelectric conversion apparatus may include a method of detecting a difference from a previous image instead of sequentially capturing images, and a method of clipping an image from constantly-recorded images.

FIG. 12B is a diagram illustrating a schematic view of an example of an electronic device. An electronic device 1200 includes a display unit 1201, an operation unit 1202, and a housing 1203. The housing 1203 may include a circuit, a printed substrate including the circuit according to the present embodiment, a battery, and a communication unit. The operation unit 1202 may be a button or may be a touch panel type response unit. The operation unit 1202 may be a biometric authentication unit that unlocks the electronic device 1200 by recognizing a fingerprint. The electronic device 1200 including a communication unit can also be called a communication device. The electronic device 1200 may further include a camera function by including a lens and an image sensor. An image captured using the camera function is displayed on the display unit 1201. Examples of the electronic device 1200 include a smartphone, a laptop personal computer, and the like.

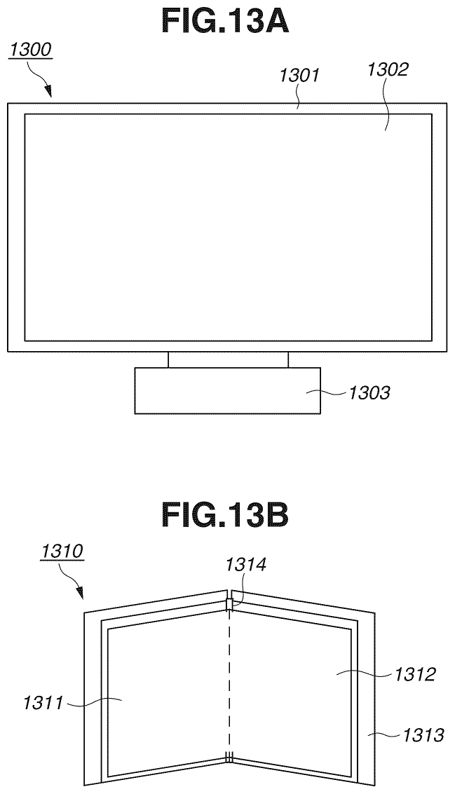

FIGS. 13A and 13B are diagrams each illustrating a schematic view of an example of a display device. FIG. 13A illustrates a display device, such as a television monitor or a personal computer (PC) monitor. A display device 1300 includes a frame 1301 and a display unit 1302. An organic light emitting device is used in the display unit 1302. The display device 1300 further includes a base 1303 supporting the frame 1301 and the display unit 1302. The shape of the base 1303 is not limited to the shape illustrated in FIG. 13A. A lower side of the frame 1301 may also serve as a base. The frame 1301 and the display unit 1302 may have a curved shape. The curvature radius of the curved shape may be 5000 mm or more and 6000 mm or less.

FIG. 13B is a schematic view illustrating another example of the display device. A display device 1310 illustrated in FIG. 13B has a foldable configuration and is a so-called foldable display device. The display device 1310 includes a first display unit 1311, a second display unit 1312, a housing 1313, and a folding point 1314. The first display unit 1311 and the second display unit 1312 include an organic light emitting device. The first display unit 1311 and the second display unit 1312 may form a seamless one display device. The first display unit 1311 and the second display unit 1312 can be divided at the folding point 1314. The first display unit 1311 and the second display unit 1312 may individually display different images, or the first display unit 1311 and the second display unit 1312 may display one image in cooperation.

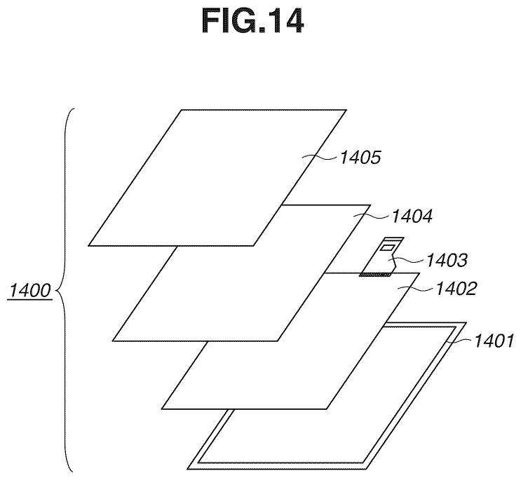

FIG. 14 is a diagram illustrating a schematic view of an example of an illumination apparatus. An illumination apparatus 1400 includes a housing 1401, a light source 1402, a circuit substrate 1403, an optical filter 1404, and a light diffusion unit 1405. The light source 1402 includes an organic light emitting device. The optical filter 1404 may be a filter that enhances color rendering properties of the light source 1402. The light diffusion unit 1405 can effectively diffuse light of the light source 1402 by lighting up, and can deliver light to a wide range. The optical filter 1404 and the light diffusion unit 1405 may be disposed on a light emission side of illumination. A cover may be disposed at an outermost portion as necessary.

The illumination apparatus is an apparatus that illuminates the inside of a room, for example. The illumination apparatus may emit light with any color of a white color, a daylight white color, and other colors from blue to red. The illumination apparatus may include a light control circuit for controlling these colors. The illumination apparatus 1400 includes an organic light emitting device and a power circuit connected to the organic light emitting device. The power circuit is a circuit that converts an alternating-current voltage into a direct-current voltage. A color temperature of the white color is 4200 K and a color temperature of the daylight white color is 5000 K. The illumination apparatus 1400 may include a color filter.

The illumination apparatus 1400 may also include a heat release unit. The heat release unit releases heat in the apparatus to the outside of the apparatus, and metal with high specific heat, liquid silicon, or the like may be used.

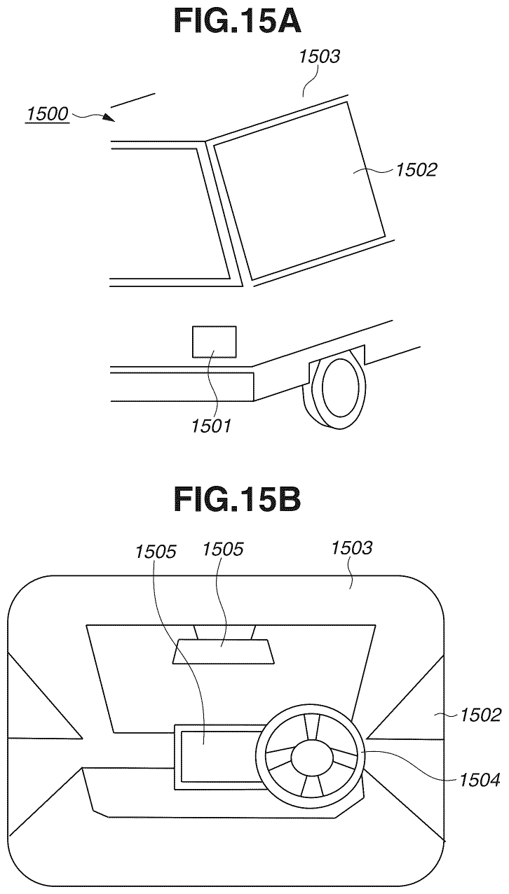

FIG. 15A is a diagram illustrating a schematic view of an automobile serving as an example of a movable body. As illustrated in FIG. 15A, the automobile includes a tail lamp serving as an example of an illumination device. An automobile 1500 may include a tail lamp 1501 and may be configured to light the tail lamp 1501 when a brake operation is performed.

The tail lamp 1501 includes an organic light emitting device. The tail lamp 1501 may include a protection member that protects the organic light emitting device. The material of the protection member is not limited as long as the protection member is transparent and has a certain level of high strength, but it is desirable that the protection member is made of polycarbonate. A furandicarboxylic acid derivative or an acrylonitrile derivative may be mixed with polycarbonate.

The automobile 1500 may include a vehicle body 1503 and a window 1502 attached to the vehicle body 1503. The window 1502 may be a transparent display as long as the window 1502 is not a window for checking the front side and the back side of the automobile 1500. The transparent display includes an organic light emitting device. In this case, a transparent member is used as a material of an electrode included in the organic light emitting device.

As illustrated in FIG. 15B, the automobile 1500 includes a steering wheel 1504 that controls the moving direction of the movable body, and a display unit 1505 that displays a map, the position, and the turn direction of the movable body, and is mounted on the vehicle body 1503. The display unit 1505 includes an organic light emitting device.

Here, an example in which the movable body is an automobile will be described, but the movable body may be a ship, an airplane, or a drone. The movable body includes a main body, and an illumination device and a display unit that are provided on the main body. The illumination device emits light to report the position of the main body. Either the illumination device or the display includes an organic light emitting device.

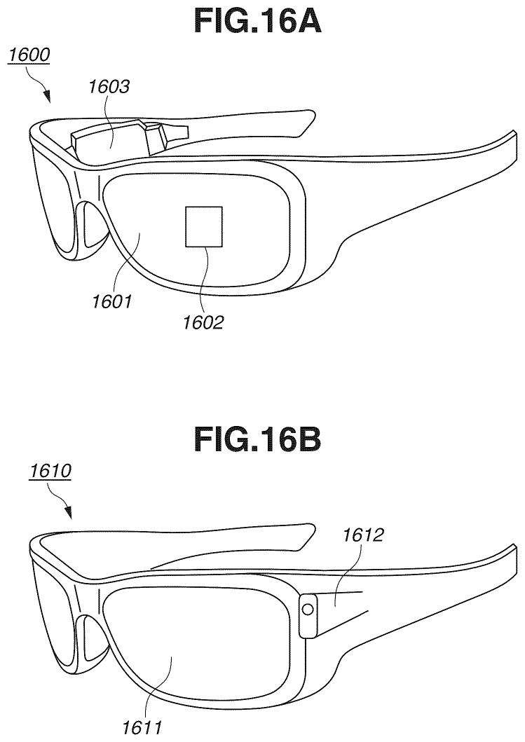

An application example of the above-described display device will be described with reference to FIGS. 16A and 16B. The display device can be applied to a system that can be worn as a wearable device, such as a smart glass, a head-mounted display (HMD), or a smart contact lens, for example. An image capturing display device to be used in such an application example includes an imaging apparatus that can photoelectrically convert visible light, and a display device that can emit visible light.

FIG. 16A is a diagram illustrating a schematic view of eyeglasses 1600 (smart glass) according to an application example. An imaging apparatus 1602, such as a complementary metal-oxide semiconductor (CMOS) sensor or a single photon avalanche diode (SPAD) sensor, is disposed on the front surface of a lens 1601 of the eyeglasses 1600. The display device according to each of the above-described embodiments is provided on the back surface of the lens 1601.

The eyeglasses 1600 further include a control apparatus 1603. The control apparatus 1603 functions as a power source that supplies power to the imaging apparatus 1602 and the display device according to each of the above-described embodiments. The control apparatus 1603 controls operations of the imaging apparatus 1602 and the display device. In the lens 1601, an optical system for condensing light on the imaging apparatus 1602 is formed.

FIG. 16B is a diagram illustrating eyeglasses 1610 (smart glass) according to an application example. The eyeglasses 1610 include a control apparatus 1612, and the control apparatus 1612 is provided with an imaging apparatus equivalent to the imaging apparatus 1602 in FIG. 16A, and a display device. In a lens 1611, an optical system for projecting light emission from the imaging apparatus and the display device in the control apparatus 1612 is formed, and an image is projected onto the lens 1611. The control apparatus 1612 functions as a power source that supplies power to the imaging apparatus and the display device, and controls operations of the imaging apparatus and the display device. The control apparatus 1612 may include a visual line detection unit that detects a visual line of a wearer. Infrared light may be used in the detection of a visual line. An infrared light emission unit emits infrared light onto an eyeball of a user looking at a displayed image. An imaging unit including a light receiving element detects reflected light of the emitted infrared light that has been reflected on the eyeball whereby a captured image of the eyeball is obtained. With a reduction unit for reducing light from the infrared light emission unit to a display unit in a planar view, a decline in image quality is reduced.

From a captured image of an eyeball that has been obtained by image capturing using infrared light, the control apparatus 1612 detects a visual line of a user with respect to a displayed image. Any known method may be applied to visual line detection that uses a captured image of an eyeball. As an example, a visual line detection method that is based on a Purkinje image obtained by reflection of irradiation light on a cornea can be used. More specifically, visual line detection processing based on the pupil center corneal reflection is performed. By calculating an eye vector representing the direction (rotational angle) of an eyeball, based on an image of a pupil and a Purkinje image that are included in a captured image of the eyeball, using the pupil center corneal reflection, a visual line of a user is detected.

The display device according to the present embodiment may include an imaging apparatus including a light receiving element, and control a displayed image on the display device based on visual line information of the user from the imaging apparatus. Specifically, in the display device, a first eyeshot region viewed by the user, and a second eyeshot region other than the first eyeshot region are determined based on the visual line information. The first eyeshot region and the second eyeshot region may be determined by a control apparatus of the display device, or the first eyeshot region and the second eyeshot region determined by an external control apparatus may be received. In a display region of the display device, a display resolution in the first eyeshot region may be controlled to be higher than a display resolution in the second eyeshot region. In other word, a resolution in the second eyeshot region may be made lower than a resolution in the first eyeshot region.

The display region includes a first display region and a second display region different from the first display region. Based on the visual line information, a region with high priority is determined from the first display region and the second display region. The first display region and the second display region may be determined by a control apparatus of the display device, or the first display region and the second display region determined by an external control apparatus may be received. A resolution of a region with high priority may be controlled to be higher than a resolution of a region other than the region with high priority. In other words, a resolution of a region with relatively-low priority may be set to a low resolution.

Artificial intelligence (AI) may be used to determine the first eyeshot region and a region with high priority. The AI may be a model configured to estimate an angle of a visual line and a distance to a target existing at the end of the visual line, from an image of an eyeball by using data, as training data, including an image of the eyeball and a direction in which the eyeball in the image actually gives a gaze. An AI program may be included in the display device, may be included in the imaging apparatus, or may be included in an external apparatus. In a case where an external apparatus includes the AI program, the AI program is transmitted to the display device via communication.

In a case where display control is performed based on visual line detection, the present invention can be desirably applied to a smart glass further including an imaging apparatus that captures an image of the outside. The smart glass can display external information obtained by image capturing, in real time.

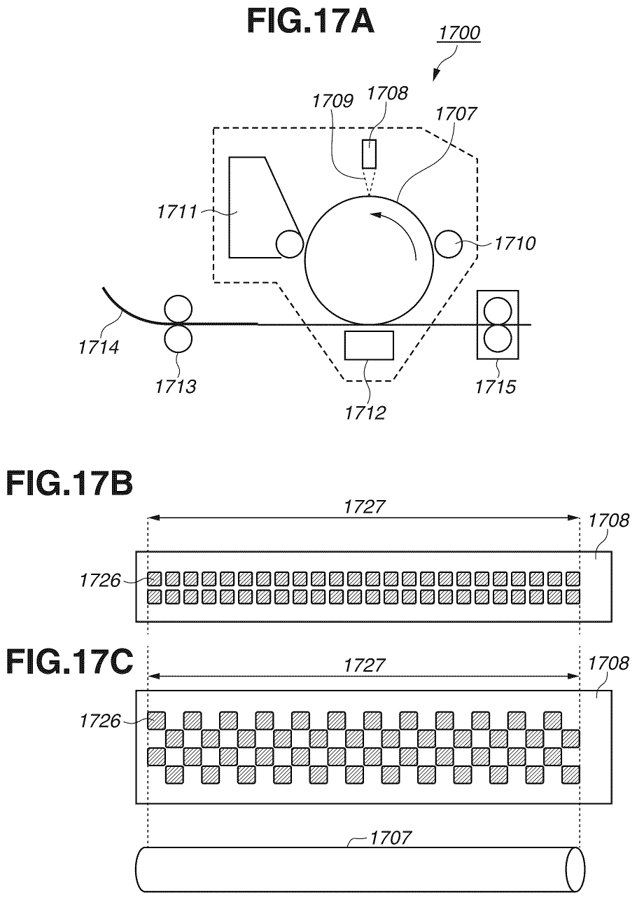

FIG. 17A is a diagram illustrating a schematic view of an example of an image forming apparatus. An image forming apparatus 1700 is an electrophotographic image forming apparatus and includes a photosensitive member 1707, an exposure light source 1708, a charging unit 1710, a development unit 1711, a transfer device 1712, a conveyance roller 1713, and a fixing device 1715.

Light 1709 is emitted from the exposure light source 1708, and an electrostatic latent image is formed on the surface of the photosensitive member 1707. The exposure light source 1708 includes an organic light emitting device. The development unit 1711 includes toner. The charging unit 1710 charges the photosensitive member 1707. The transfer device 1712 transfers a developed image onto a recording medium 1714. The conveyance roller 1713 conveys the recording medium 1714. The recording medium 1714 is paper, for example. The fixing device 1715 fixes an image formed on the recording medium 1714.

FIGS. 17B and 17C are diagrams each illustrating the exposure light source 1708 and a schematic view of a state in which a plurality of light emitting units 1726 are arranged on an elongated substrate. An arrow 1727 indicates a direction parallel to the axis of the photosensitive member 1707 and a column direction in which organic light emitting devices are arrayed. This column direction is the same as a direction of an axis around which the photosensitive member 1707 rotates. This direction can also be called a long axis direction of the photosensitive member 1707. FIG. 17B illustrates a configuration in which the light emitting units 1726 are arranged along the long axis direction of the photosensitive member 1707. The light emitting units 1726 include organic light emitting devices. FIG. 17C illustrates a configuration different from the configuration illustrated in FIG. 17B and illustrates a configuration in which the light emitting units 1726 are alternately arranged in the column direction on first and second columns. The first and second columns are arranged at different positions in a row direction. A plurality of light emitting units 1726 are arranged at intervals on the first column. The second column includes light emitting units 1726 at positions corresponding to the intervals between the light emitting units 1726 on the first column. That is, a plurality of light emitting units 1726 are arranged at intervals also in the row direction. The arrangement illustrated in FIG. 17C can be rephrased as a state in which light emitting units 1726 are arranged in a grid, or a state in which light emitting units 1726 are arranged in a houndstooth pattern or a checkered pattern, for example.

As described above, with an organic light emitting device, stable display for a long time with good image quality can be provided.

According to the present disclosure, a defect in an opening of an evaporation mask is less likely to occur, and the generation of a foreign substance is prevented, whereby a deposited film adapted to high-density pixels is able to be formed.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-148394, filed Aug. 30, 2024, which is hereby incorporated by reference herein in its entirety.

What is claimed is:

1. An evaporation mask made of metal, the evaporation mask comprising:
a first surface on a deposition source side;
a second surface on a side facing a deposition receiving substrate; and
an opening penetrating from the first surface to the second surface,
wherein a side wall surrounding the opening has a boundary between the first surface and the second surface and has a taper shape from the boundary toward the first surface and a taper shape from the boundary toward the second surface, and
wherein, in a cross-section passing through the first surface, the second surface, and the opening, when a taper angle formed by the side wall and an extended line drawn from the first surface onto the opening is denoted by θ₁, and another taper angle formed by the side wall and an extended line drawn from the second surface onto the opening is denoted by θ₂, both the taper angles θ₁ and θ₂ are sharp angles and satisfy θ₁>θ₂.

2. The evaporation mask according to claim 1, wherein, in the cross-section, when a length of the side wall in a first direction parallel to the second surface at the boundary is denoted by W, and a length from the boundary to the second surface in a second direction vertical to the second surface is denoted by t₂, θ₂≥Arctan(2t₂/W) is satisfied.

3. The evaporation mask according to claim 1, wherein, in the cross-section, when a length of the side wall in a first direction parallel to the second surface at the boundary is denoted by W [μm], and a length from the boundary to the second surface in a second direction vertical to the second surface is denoted by t₂, 0.01 [μm]≤t₂≥(W/2) tan θ₂ is satisfied.

4. The evaporation mask according to claim 1, wherein a thickness of the side wall in a direction vertical to the second surface is less than or equal to 8.8 μm.

5. The evaporation mask according to claim 1, wherein the metal is an alloy of a metal selected from iron, nickel, and cobalt.

6. The evaporation mask according to claim 1, wherein the evaporation mask includes a mask frame on an outer periphery of the second surface.

7. A manufacturing method of an evaporation mask, the manufacturing method comprising:
providing a seed layer on a surface of a substrate;
forming, on the surface of the substrate, a first resist pattern having a taper angle θ₂ as an angle with respect to the surface;
forming, on the first resist pattern, a second resist pattern having a taper angle θ₁ as an angle with respect to the surface;
electrically precipitating a metal film in a space in the first and second resist patterns;
forming an opening in the metal film by removing the first and second resist patterns; and
removing the substrate and the seed layer from the metal film in which the opening is formed,
wherein both the taper angles θ₁ and θ₂ are sharp angles and satisfy θ₁>θ₂.
